(19) United States
(12) Patent Application Publication
(10) Pub. No.: US 2024/0194578 A1
(43) Pub. Date: Jun. 13, 2024

(54) EMBEDDED DEVICE PACKAGE SUBSTRATE AND MANUFACTURING METHOD THEREFOR

(71) Applicant: Zhuhai ACCESS Semiconductor Co., Ltd, Guangdong (CN)

(72) Inventors: Xianming CHEN, Guangdong (CN); Yejie HONG, Guangdong (CN); Gao HUANG, Guangdong (CN); Benxia HUANG, Guangdong (CN); Wenjian LIN, Guangdong (CN)

(21) Appl. No.: 18/377,442

(22) Filed: Oct. 6, 2023

(30) Foreign Application Priority Data
Dec. 29, 2022 (CN) 2022117169596

(51) Int. Cl. H01L 23/498; H01L 21/48; H01L 23/31

(52) U.S. Cl. CPC H01L 23/49838; H01L 21/4853; H01L 23/3121; H01L 23/49822; H01L 23/49833

(57) ABSTRACT

An embedded device package substrate includes a line board including a first insulating layer and a first line layer located on an upper surface of the first insulating layer, a core layer covering the first line layer and including a preset opening, a device embedded in the preset opening, a packaging layer covering the core layer and filling the gap between the core layer and the device, and an outer line layer located on the packaging layer. The outer line layer is connected to a terminal of the device by a first conductive column penetrating through the packaging layer and to the first line layer by a second conductive column penetrating through the core layer and the packaging layer.

### CROSS-REFERENCE TO RELATED APPLICATION AND CLAIM OF PRIORITY

This application claims the benefit under 35 USC § 119 of Chinese Patent Application No. 2022117169596, filed on Dec. 29, 2022, in the China Intellectual Property Office, the entire disclosure of which is incorporated herein by reference for all purposes.

### BACKGROUND

### 1. Technical Field

The present disclosure relates to the technical field of semiconductor packaging, and more particularly to an embedded device package substrate and a manufacturing method therefor.

### 2. Background Art

With the increasing development of electronic technology, the performance requirements for electronic products are higher and higher, which makes electronic elements and substrate lines more and more complex. At the same time, electronic products are required to be smaller and smaller and thinner and thinner. Therefore, high-density integration, miniaturization, and multifunction of electronic device package substrates such as chips are an inevitable trend. In order to realize the multi-function, high performance, and miniaturization of electronic products, how to embed and package active and passive devices such as chips into a substrate with high efficiency and low cost is an important research direction in the current semiconductor packaging industry.

The existing board-level chip package fanout technologies include: manufacturing a polymer frame having a rectangular cavity in advance, and then embedding and packaging a chip in the rectangular cavity, and connecting the chip and the polymer frame by manufacturing a re-wiring layer. With regard to a multi-layer chip embedded package substrate, on the basis of the above-mentioned packaging, layer-adding manufacturing is also performed on two sides. With such a solution, a polymer frame having a cavity needs to be manufactured in advance, making the processing flow longer. The cavity of the polymer frame needs to be plated with a sacrificial copper column and then etched to remove the sacrificial copper column, thereby forming a cavity, resulting in a large waste of material costs.

In addition, the chip embedded packaging flow is located at the front in the whole processing flow. Because the chip is thin and fragile, in the subsequent long processing procedure, the proportion of chip scrapping is relatively high, and the scrapping of the substrate during the processing procedure can also lead to chip waste.

### SUMMARY

In view of the above, it is an object of the present disclosure to propose an embedded device package substrate and a manufacturing method therefor.

In view of the above objects, in the first aspect, the present disclosure provides an embedded device package substrate including:
a line board comprising a first insulating layer and a first line layer located on an upper surface of the first insulating layer;
a core layer covering the first line layer and comprising a preset opening;
a device embedded in the preset opening;
a packaging layer covering the core layer and filling a gap between the core layer and the device; and
an outer line layer located on the packaging layer;
wherein the outer line layer is connected to a terminal of the device by a first conductive column penetrating through the packaging layer and to the first line layer by a second conductive column penetrating through the core layer and the packaging layer.

In the second aspect, the present disclosure provides a manufacturing method for an embedded device package substrate, the manufacturing method includes:
(a) preparing a line board, wherein the line board comprises a first insulating layer and a first line layer located on an upper surface of the first insulating layer;
(b) forming a viscous core dielectric layer on the first line layer;
(c) adhering a back side of a device on the viscous core dielectric layer;
(d) laminating a core layer over the viscous core dielectric layer, wherein the core layer comprises a preset opening to accommodate the device;
(e) laminating a packaging layer on the core layer to package the device;
(f) forming a first conductive column connected to a terminal of the device and a second conductive column connected to the first line layer; and
(g) forming an outer line layer on the packaging layer, wherein the outer line layer is in conductive connection with the terminal of the device through the first conductive column, and the outer line layer is in conductive connection with the first line layer through the second conductive column.

It can be seen from the above-mentioned description that the present disclosure provides an embedded device package substrate and a manufacturing method therefor. A line board is firstly manufactured, then a core layer having a preset opening is used to accommodate a device, then a packaging layer is used to embed and package the device, and finally, an outer line layer is formed. Since devices such as a chip are embedded and packaged after the line substrate is manufactured, device waste caused by the scrapping of the line substrate can be prevented, and at the same time, the formation of the preset opening of the core layer is simple without requiring sacrificing copper columns, thereby effectively reducing material costs.

### BRIEF DESCRIPTION OF THE DRAWINGS

In order to explain the technical solutions in of the present disclosure or the related art more clearly, the following will briefly introduce the drawings needed in the description of the embodiments and the related art. Obviously, the drawings in the following description are merely embodiments of the present disclosure. For those of ordinary skills in the art, without involving creative efforts, other drawings can be obtained from these drawings.

FIG. 1 is a schematic structural diagram of an embedded device package substrate according to one embodiment of the present disclosure;

FIG. 2 is a schematic structural diagram of an embedded device package substrate according to another embodiment of the present disclosure;

FIGS. 3A-3I show schematic cross-sectional views of intermediate structures at various steps of a manufacturing method for an embedded device package substrate according to one embodiment of the present disclosure.

### DETAILED DESCRIPTION OF THE INVENTION

In order to make the purpose, technical solutions, and advantages of this disclosure clearer, the following is a detailed explanation of this disclosure in conjunction with specific embodiments and with reference to the accompanying drawings.

It needs to be noted that, unless otherwise defined, technical or scientific terms used in the embodiments of the present disclosure shall have the ordinary meaning as understood by one of ordinary skill in the art to which the present disclosure belongs. The use of “first”, “second”, and similar terms in the embodiments of the present disclosure does not denote any order, quantity, or importance, but rather is used to distinguish different constituting parts. The words “comprising” or “include”, and the like, mean that the elements or articles preceding the word encompass the elements or articles listed after the words and equivalents thereof, but do not exclude other elements or articles. Words such as “connection” or “connected” are not limited to physical or mechanical connections, but can include electrical connections, whether direct or indirect. The terms “up”, “down”, “left”, “right”, etc. are only used to represent relative positional relationships. When the absolute position of the described object changes, the relative positional relationship may also change accordingly.

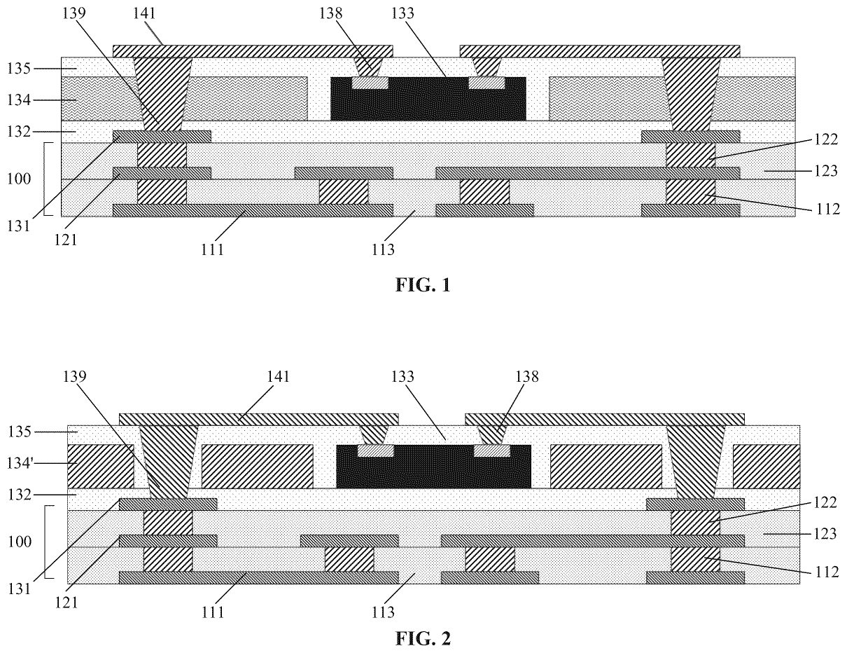

Referring to FIGS. 1 and 2, there are shown schematic structural views of an embedded device package substrate provided by an embodiment of the present disclosure. Specifically, the embedded device package substrate includes: a line board 100, wherein the line board 100 includes a first insulating layer 123 and a first line layer 131 located on an upper surface of the first insulating layer; core layers 134, 134′ located on the first insulating layer 123 and the first line layer 131, the core layer s134, 134′ including preset openings; a device 133 embedded in the preset opening; a packaging layer 135 covering the core layers 134, 134′ and the device 133; and an outer line layer 141 provided on the packaging layer 135. The outer line layer 141 is connected to a terminal of the device 133 through a first conductive column 138 penetrating through the packaging layer 135, and is connected to the first line layer 131 through a second conductive column 139 penetrating through the core layers 134, 134′ and the packaging layer 135.

In some embodiments, the line board 100 may be a multilayer line substrate, e.g., 2 layers, 3 layers, or 4 layers, etc. As shown in FIGS. 1 and 2, the line board 100 may include a first insulating layer 123 and a second insulating layer 113 laminated in the thickness direction. The first insulating layer 123 includes a first line layer 131 on the upper surface of the first insulating layer 123 and a second line layer 121 on a lower surface of the first insulating layer 123. The first line layer 131 and the second line layer 121 are conductively connected through a third conductive column 122 penetrating through the first insulating layer 123. The second insulating layer 113 includes a third line layer 111 on the lower surface of the second insulating layer 113. The third line layer 111 can be conductively connected to the second line layer 121 through a fourth conductive column 112 penetrating through the second insulating layer 113.

The material of the first insulating layer 123 may include a resin material such as one selected from a group consisting of a liquid crystal high molecular polymer, a BT (bismaleimide triazine) resin, a semi-cured Prepreg, an ABF (Ajinomoto build-up film), an epoxy resin, and a polyimide resin, which is not limited by the present disclosure. The second insulating layer 113 and the first insulating layer 123 may be resin materials of the same or different textures, which is not limited by the present disclosure.

As could be understood by those skilled in the art, the number of insulating layers included in the line board 100 is not limited to 2 layers, but may be 3 layers, 4 layers, etc.

The line board mentioned in this implementation mode may include a coreless substrate or a core substrate, and may be selected according to actual needs.

In some embodiments, the embedded device package substrate further includes: a viscous core dielectric layer 132 provided on the first line layer 131, the viscous core dielectric layer 132 being between the core layer 134 and the first insulating layer 123. The material of the viscous core dielectric layer 132 is typically a dielectric material that is viscous at room temperature or under heat, and the viscous core dielectric layer 132 may be used to temporarily secure a device, such as a chip. Alternatively, the viscous core dielectric layer 132 is a thermosetting dielectric material or a photosensitive dielectric material.

The device 133 may be an active element (e.g., a transistor, an IC device, a logic circuit element, and a power amplifier) or a passive element (a capacitor, an inductor, and a resistor) or a combination thereof. The number of devices 133 is not limited to only one.

Embedded packaging materials and storey adding dielectric materials are usually made of fiberglass-free resin materials, but their coefficient of thermal expansion (CTE) is relatively large, making it difficult to control the warping during the subsequent processing.

In view of this, in some embodiments, a fiberglass resin material may be selected for the core layer 134. The fiberglass resin material has high strength, which helps to reduce the warping of the substrate.

In addition, the resin material has a small heat conductivity coefficient, which cannot satisfy the high heat dissipation requirement of a high-computation-amount chip. Therefore, in some embodiments, the core layer 134 may be selected from a metal material, such as a copper plate. Metal materials have high heat dissipation capacity, and can better meet the heat dissipation requirements of chips.

Optionally, the packaging layer 135 includes a fiberglass-free resin material. The fiberglass-free resin material has good fillability and enables good packaging of the device 133. Further, the fiberglass-free resin material may be selected from one or more of liquid crystal high molecular polymer, BT resin, semi-cured prepreg, ABF thin film, epoxy resin, and polyimide resin.

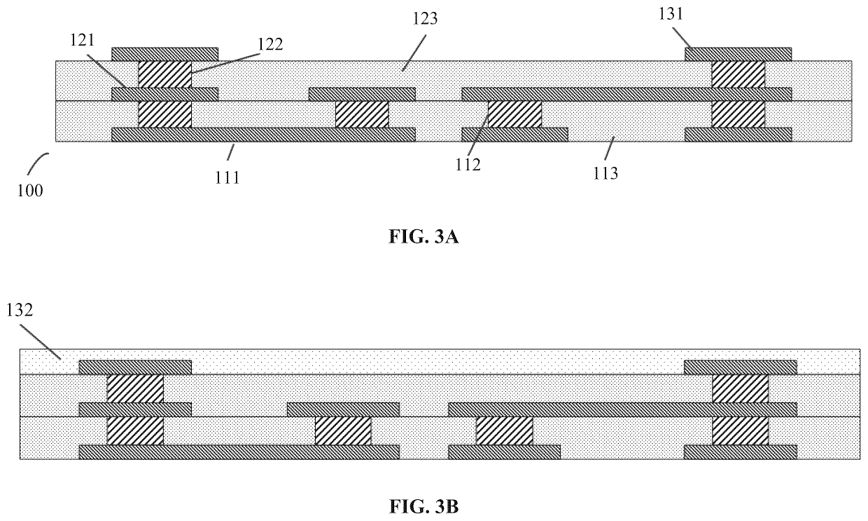

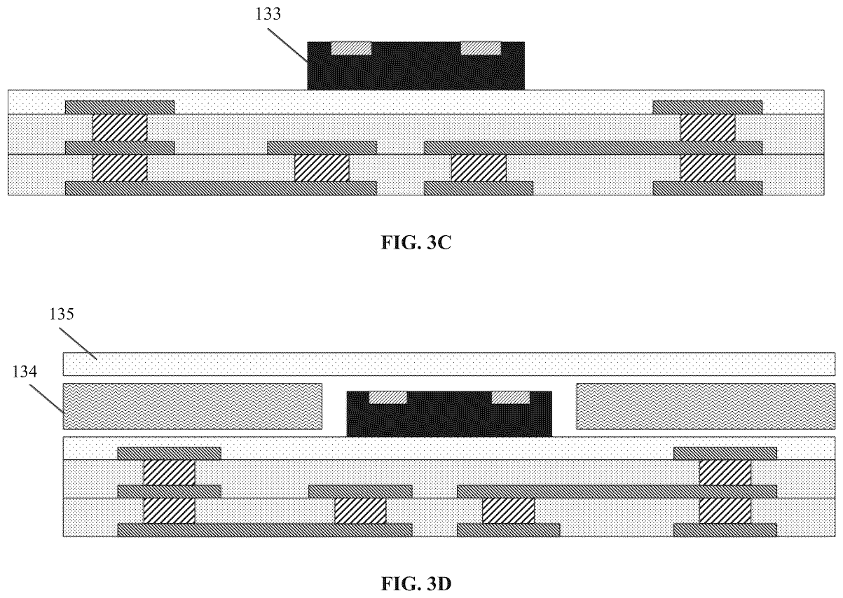

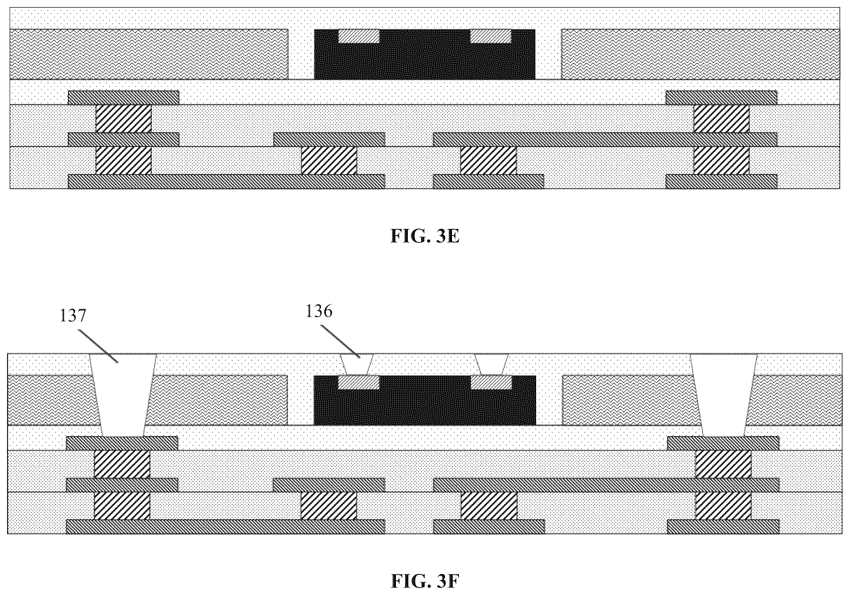

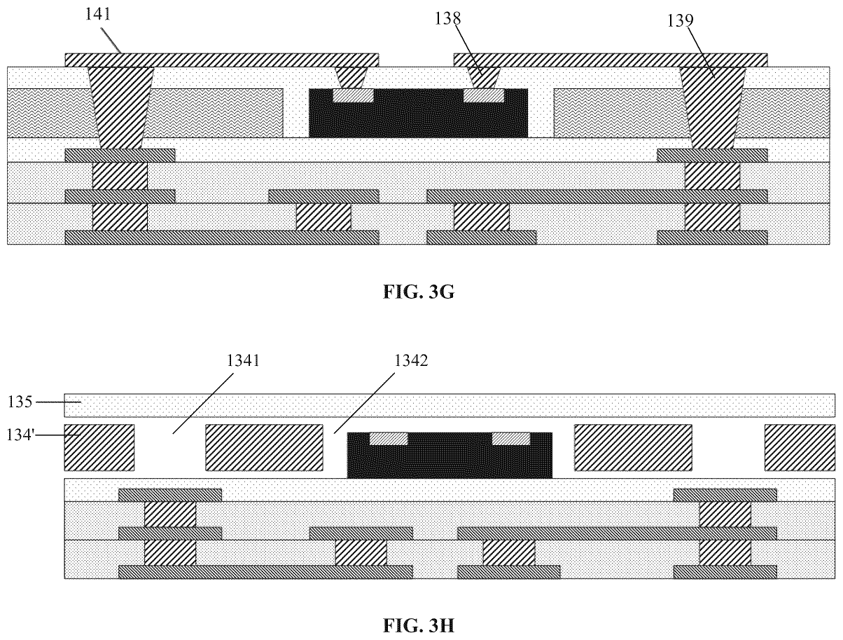

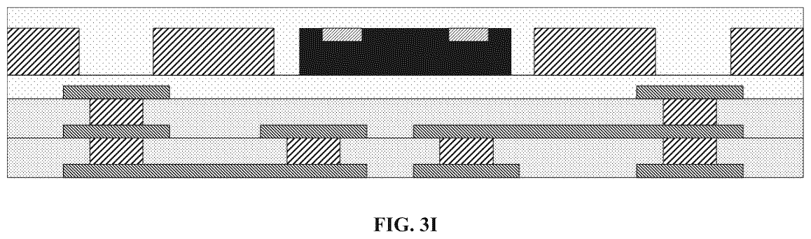

In some embodiments, referring to FIGS. 2 and 3H, when the core layer 134′ is, for example, a metal material, the preset opening may include a first opening 1342 in which the device 133 is embedded and a second opening 1341; a second conductive column 139 is accommodated in the second opening 1341. Providing a second opening helps to reduce the difficulty of forming the second conductive column 139, and the process is simpler and easier to implement.

Further, a packaging layer 135 fills a gap between the core layer 134′ and the device 133, and the core layer 134′ and the second conductive column 139.

Optionally, the heights of the core layers 134 and 134′ are greater than or equal to the height of the device 133.

FIGS. 3A-3I show schematic cross-sectional views of intermediate structures at various steps of a manufacturing method for an embedded device package substrate according to one embodiment of the present disclosure.

The manufacturing method includes the steps of: manufacturing a line board 100-step a, as shown in FIG. 3A. The line board 100 includes a first insulating layer 123 and a first line layer 131 on an upper surface of the first insulating layer 123. The other layer structures of the line board 100 are as previously described and will not be described again.

The line board mentioned in the present implementation mode can be replaced with a printed circuit board, and can be selected according to needs, and the subsequent process is merely demonstrated as a line board. But the manufacturing method is not limited to being only applicable to a line board. The number of insulating layers included in the line board is not limited to 2 layers, and the subsequent process is only demonstrated for the line board including 2 insulating layers.

Alternatively, the line board can be prepared by a tenting (masking method) process, a MSAP process, or an SAP process, and a multilayer insulating layer can be prepared by a Coreless technique or a conventional CCL storey-adding technique; and the interlayer conducting mode can be copper column conduction, laser hole conduction, or mechanical hole conduction, etc. and the details are not limited.

Next, a viscous core dielectric layer 132 is formed on the first insulating layer 123 and the first line layer 131-step b, as shown in FIG. 3B.

Typically, the viscous core dielectric layer 132 is tacky at ambient temperature or under heat to bond a fastening device. Alternatively, the viscous core dielectric layer is a thermosetting dielectric material or a photosensitive dielectric material.

In some implementations, the process of forming the viscous core dielectric layer 132 is selected from printing, pressing fit, and coating. Illustratively, the viscous core dielectric layer 132 may be formed by spin coating or/and coating a liquid resin, or may be formed by pressing fit a dielectric material having a conformal function in a dry film type.

Alternatively, the thickness of the viscous core dielectric layer 132 is 10-40 μm, such as 10 μm, 15 μm, 30 μm, and 40 μm.

The back side of the device 133 is then attached to the viscous core dielectric layer 132-step c, as shown in FIG. 3C. Specifically, the device 133 can be adhered on the viscous core dielectric layer 132 on the surface of the first insulating layer 123 by a chip mounter. When adhering, whether to heat can be selected according to the strength of the viscidity of the viscous core dielectric layer 132. For example, when the viscidity is low, the device 133 can be heated or the line board can be heated by a chip mounter with a heating function before adhering the device 133.

Next, a core layer 134 and a packaging layer 135 are stacked on the viscous core dielectric layer; the core layer 134 includes a preset opening to accommodate the device 133-step d, as shown in FIG. 3D.

Alternatively, the core layer 134 may include a fiberglass resin material. Alternatively, the preset opening is prepared by a stamping or drilling-milling process. Material waste can be effectively reduced, the processing cycle can be shortened, and the processing cost can be reduced compared with the prior art which requires sacrificial copper columns to prepare a cavity.

Optionally, the packaging layer includes a fiberglass-free resin material. Illustratively, fiberglass-free resin materials are selected from one or more of liquid crystal high molecular polymer, BT resin, semi-cured prepreg, ABF thin film, epoxy resin, and polyimide resin.

In an alternative implementation mode, as shown in FIG. 3H, the core layer 134′ may be a metal material, such as a copper plate. The preset opening includes a first opening 1342 and a second opening 1341. The first opening 1342 is used for embedding the device 133. The second opening 1341 is for accommodating a second conductive column 139.

The packaging layer 135 is then pressed fit to package the device and cure-step e. As shown in FIG. 3E, the material of the packaging layer 135 fills the gap between the core layer 134′ and the device 133 to achieve embedded packaging of the device 133. Alternatively, when the core layer 134′ is a metal material, the curing result is as shown in FIG. 3I. The material of the packaging layer 135 also fills the second opening 1341.

Then, forming a first conductive blind hole 136 exposing the terminal of the device 133 in the packaging layer 135; and forming a second conductive blind hole 137 in the packaging layer 135, the core layers 134 and 134′, and the viscous core dielectric layer 132, the second conductive blind hole 137 exposing the first line layer 131-step f, as shown in FIG. 3F. Alternatively, the first conductive blind hole 136 and the second conductive blind hole 137 are formed by a laser drilling process.

Then, a first conductive column 138 is formed in the first conductive blind hole 136, a second conductive column 139 is formed in the second conductive blind hole 137, and an outer line layer 141 is formed on the upper surface of the packaging layer 135; the outer line layer 141 is connected to the terminal through the first conductive column 138, and the outer line layer 141 is connected to the first line layer 131 through the second conductive column 139-step g, as shown in FIG. 3G.

With such a solution, embedding the device before the outer line layer 141 is prepared helps to reduce the flow after the device is packaged, which can reduce the risk of the device being scrapped and also reduce the waste of the device caused by the substrate being scrapped.

In some embodiments, step (g) includes: forming a first metal seed layer on the bottom and side walls of the first conductive blind hole 136 and the second conductive blind hole 137 and the upper surface of the packaging layer 135; electroplating the first conductive blind hole 136 to form a first conductive column 138, and the second conductive blind hole 137 to form a second conductive column 139, and performing electroplating to form a second copper layer on the upper surface of the packaging layer 135; applying a first photoresist layer on the second copper layer, and exposing and developing the first photoresist layer to form a first feature pattern; etching the exposed second copper layer in the first feature pattern to form an outer line layer 141; and removing the first photoresist layer.

In some alternative embodiments, step (g) includes: forming a first metal seed layer on the bottom and side walls of the first conductive blind hole 136 and the second conductive blind hole 137 and the upper surface of the packaging layer 135; applying a second photoresist layer on the first metal seed layer, and exposing and developing the second photoresist layer to form a second feature pattern; electroplating the first conductive blind hole 136 to form a first conductive column 138, and the second conductive blind hole 137 to form a second conductive column 139, and performing electroplating on the upper surface of the packaging layer 135 to form an outer line layer 141; removing the second photoresist layer; and etching the exposed first metal seed layer.

The disclosed embodiments are intended to cover all such alternatives, modifications, and variances which fall within the broad scope of the appended claims. Therefore, any omissions, modifications, equivalent substitutions, improvements, etc. made within the spirit and principles of the disclosed embodiments shall be included in the scope of protection of the present disclosure.

What is claimed is:

1. An embedded device package substrate comprising:
a line board comprising a first insulating layer and a first line layer located on an upper surface of the first insulating layer;
a core layer covering the first line layer and comprising a preset opening;
a device embedded in the preset opening;
a packaging layer covering the core layer and filling a gap between the core layer and the device; and
an outer line layer located on the packaging layer,
wherein the outer line layer is connected to a terminal of the device by a first conductive column penetrating through the packaging layer and to the first line layer by a second conductive column penetrating through the core layer and the packaging layer.

2. The embedded device package substrate of claim 1, further comprising:
a viscous core dielectric layer on the first line layer, the viscous core temporarily fixing the device with its own viscidity.

3. The embedded device package substrate of claim 1, wherein the core layer comprises a fiberglass resin material or a metal material.

4. The embedded device package substrate of claim 1, wherein the packaging layer comprises a fiberglass-free resin material.

5. The embedded device package substrate of claim 4, wherein the fiberglass-free resin material is selected from the group consisting of liquid crystal high molecular polymer, BT resin, semi-cured prepreg, ajinomoto build-up film, epoxy resin, polyimide resin, and a combination thereof.

6. The embedded device package substrate of claim 1, wherein the preset opening comprises a first opening in which the device is embedded and a second opening in which the second conductive column is provided.

7. The embedded device package substrate of claim 1, wherein the line board further comprises a second line layer located on a lower surface of the first insulating layer and a third conductive column conductively connecting the first line layer and the second line layer.

8. A manufacturing method for an embedded device package substrate, the manufacturing method comprising:
(a) preparing a line board, wherein the line board comprises a first insulating layer and a first line layer located on an upper surface of the first insulating layer;
(b) forming a viscous core dielectric layer on the first line layer;
(c) adhering a back side of a device on the viscous core dielectric layer;
(d) laminating a core layer over the viscous core dielectric layer, wherein the core layer comprises a preset opening to accommodate the device;
(e) laminating a packaging layer on the core layer to package the device;
(f) forming a first conductive column connected to a terminal of the device and a second conductive column connected to the first line layer; and
(g) forming an outer line layer on the packaging layer, wherein the outer line layer is in conductive connection with the terminal of the device through the first conductive column, and the outer line layer is in conductive connection with the first line layer through the second conductive column.

9. The manufacturing method of claim 8, wherein the packaging layer comprises a fiberglass-free resin material; and/or the core layer comprises a fiberglass resin material or a metal material.

10. The manufacturing method of claim 8, wherein the preset opening of the core layer comprises a first opening for embedding the device and a second opening for forming the second conductive column.

11. The manufacturing method of claim 8, wherein the viscous core dielectric layer comprises a thermosetting dielectric or a photosensitive dielectric having viscosity.

12. The manufacturing method of claim 8, wherein, in step (b), a process of forming the viscous core dielectric layer is selected from the group consisting of printing, pressing fir, and coating.

13. The manufacturing method of claim 8, wherein the line board further comprises a second line layer on a lower surface of the first insulating layer and a third conductive column conductively connecting the first line layer and the second line layer.
